(19) United States
(12) Patent Application Publication
(10) Pub. No.: US 2010/0219412 A1
(43) Pub. Date: Sep. 2, 2010

(54) DISPLAY DEVICE WITH IMPROVED PIXEL LIGHT EMISSION AND MANUFACTURING METHOD OF THE SAME

(75) Inventor: Dong-won LEE, Gyeonggi-do (KR)

Correspondence Address: Innovation Counsel LLP, 21771 Stevens Creek Blvd, Ste. 200A, Cupertino, CA, 95014, US

(73) Assignee: Samsung Electronics Co., Ltd.

(21) Appl. No.: 12/763,121

(22) Filed: Apr. 19, 2010

Related U.S. Application Data
(62) Division of application No. 11/413,946, filed on Apr. 27, 2006.

(30) Foreign Application Priority Data
Jun. 2, 2005 (KR) 2005-0047273

(51) Int. Cl. H01L 33/08; H01L 33/00

(52) U.S. Cl. 257/59; 438/34; 438/158; 257/E33.053; 257/E33.005

(57) ABSTRACT

A display device with pixels capable of uniform light emission and a method of making the display device are presented. A display device has a plurality of TFTs, a protection layer formed on the TFTs, and a plurality of pixel electrodes formed on the protection layer and electrically connected to the TFTs. A wall is formed around the pixel electrode and at least a portion of the wall is spaced from the pixel electrode. A light emitting layer is formed between the wall and another wall.

### CROSS-REFERENCE TO RELATED APPLICATIONS

This application claims the benefit of priority, under 35 USC §119, of Korean Patent Application No. 2005-0047273, filed on Jun. 2, 2005 in the Korean Intellectual Property Office, the disclosure of which is incorporated herein by reference.

### BACKGROUND OF THE INVENTION

1. Field of the Invention

The present invention relates to a display device and manufacturing method of the same, and more particularly, to a display device and a manufacturing method of the same in which a light emitting layer is formed on a pixel electrode.

2. Description of the Related Art

Recently, OLED (organic light emitting diode) is becoming an increasingly popular component of flat panel displays due to advantages such as low voltage-driving, light weight, slim shape, wide angular field, and quick response. The OLED is classified into a passive-matrix type and an active-matrix type depending on the driving method. Passive-matrix type OLED is simple to manufacture, but has the disadvantage that power consumption rapidly increases with the area of display and resolution. Due to this disadvantage, passive-matrix type OLED is mainly employed only for small display devices. As for the active-matrix OLED, it is complicated to manufacture but it lends itself to easier implementation with big screens and high resolution applications.

In an active-matrix OLED, a TFT is respectively connected to each of multiple pixel areas and separately controls the organic light emitting layer in each pixel area. A pixel electrode is disposed in each pixel area and electrically separated from the other pixel electrodes so that each pixel electrode may be driven separately and independently. Further, an electrically non-conductive partition higher than the pixel electrode is formed between the pixel areas to prevent the pixel electrodes from short-circuiting. The partition is formed around the pixel electrode in a rectangular shape.

Ink is jetted onto the pixel electrode disposed between the partitions by using an ink-jet method. The ink has enough surface tension to maintain a spherical drop shape during the ink-jetting process. Due to this surface tension, it is difficult to drop the ink, properly at the corners of the rectangular partition that typically include a right angle or an acute angle. Accordingly, the ink is not spread uniformly and the quality of the pixel is compromised. Moreover, the pixel electrode and a common electrode may be short-circuited as a result, causing problems in the transmission of image signals.

### SUMMARY OF THE INVENTION

Accordingly, it is an aspect of the present invention to provide a display device that emits light uniformly and a method of manufacturing the same.

In one aspect, the invention is a display device including a plurality of thin film transistors (TFTs), a protection layer formed on the TFTs, a plurality of pixel electrodes formed on the protection layer and electrically connected to the TFTs, a wall, and a light emitting layer. The wall is formed around the pixel electrode and spaced apart from at least a portion of the pixel electrode. The light emitting layer is formed between the wall and an adjacent wall.

In another aspect, the invention is a display device that includes a plurality of TFTs, a protection layer formed on the TFTs, a plurality of pixel electrodes formed on the protection layer and electrically connected to the TFTs, a wall, and a light emitting layer. The wall at least partly exposes the protection layer and is formed around at least a portion of the pixel electrode. The light emitting layer formed between the wall and a neighboring wall.

In yet another aspect, the invention is a display device that includes a plurality of TFTs, a protection layer formed on the TFTs, a plurality of pixel electrodes formed on the protection layer and electrically connected to the TFTs, a wall, and a light emitting layer. The wall has a first portion that is spaced from the pixel electrode and a second portion that is formed on the pixel electrode. The light emitting layer formed between the wall and a neighboring wall.

In yet another aspect, the invention is a method of manufacturing a display device. The method entails forming a plurality of TFTs on an insulating substrate, depositing a protection layer on the TFTs and the insulating substrate, and forming a plurality of pixel electrodes on the protection layer, wherein the pixel electrodes are electrically connected to the TFTs. The method also entails forming a wall around the pixel electrode, wherein at least portion of the wall is spaced apart from the pixel electrode, and forming a light emitting layer between the wall and a neighboring wall.

### BRIEF DESCRIPTION OF THE DRAWINGS

The above and/or other aspects and advantages of the present invention will become apparent and more readily appreciated from the following description of the exemplary embodiments, taken in conjunction with the accompanying drawings of which:

FIG. 1 is a schematic view of a display device according to a first embodiment of the present invention;

FIG. 2 is a sectional view of FIG. 1, taken along line II-II;

FIG. 3 is a sectional view of FIG. 1, taken along line III-III;

FIGS. 4a through 4c are views illustrating a manufacturing method of the display device according to the first embodiment of the present invention;

FIG. 5 is a view showing a pixel area of a display device according to a second embodiment of the present invention; and

FIG. 6 is a view showing a pixel area of a display device according to a third embodiment of the present invention.

### DETAILED DESCRIPTION OF THE PREFERRED EMBODIMENT

Reference will now be made in detail to exemplary embodiments of the present invention, examples of which are illustrated in the accompanying drawings, wherein like reference numerals refer to like elements throughout. The embodiments are described below in order to explain the present invention by referring to the figures.

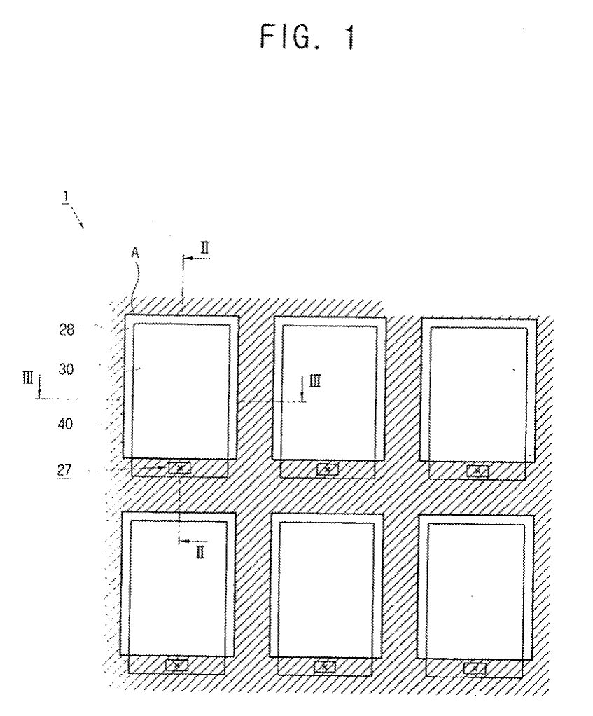

A first embodiment will be described with references to FIGS. 1 through 4.

A display device 1 includes a plurality of TFTs 20 formed on an insulating substrate 10, a protection layer 28 covering the TFT 20, and a pixel electrode 30 formed on the protection layer 28 and electrically connected to the TFT through a contact hole 27. A wall 40 is disposed between the pixel electrodes 30 and spaced apart from the pixel electrode 30. A light emitting layer 50 is formed on an area between the walls 40 and a common electrode 60 formed on the light emitting layer 50. The common electrode 50 may function as a cathode.

In the first embodiment, the TFT 20 is made of amorphous silicon. In other embodiments, the TFT 20 may be made of polysilicon. The following is a description of the TFT 20 in detail.

A gate electrode 21 is formed on the insulating substrate 10 containing an insulating substance such as glass, quartz, ceramic, plastic or the like.

A gate insulating layer 22 is made of silicon nitride (SiNx) or the like and is formed on the insulating substrate 10 and the gate electrode 21. A semiconductor layer 23 and an ohmic contact layer 24 are formed on and around the portion of the gate insulating layer 22 that is deposited on the gate electrode 21. The semiconductor layer 23 is made of amorphous silicon, and the ohmic contact layer 24 is made of n+-hydrogenated amorphous silicon highly doped with an n-type dopant. The ohmic contact layer 24 is divided in two parts with the gate electrode 21 between the two parts.

A source electrode 25 and a drain electrode 26 are formed on the ohmic contact layer 24 and the gate insulating layer 22. The source electrode 25 is disposed opposite across the gate electrode 21 from the drain electrode 26.

The protection layer 28 is formed on the source electrode 25, the drain electrode 26, and the portion of the semiconductor layer 23 that is not covered with the two electrodes 25, 26. The protection layer 28 may be made of silicon nitride (SiNx) and/or an organic substance. A contact hole 27 is formed in the protection layer 28 and extends to the drain electrode 26.

The pixel electrode 30 is formed in a substantially rectangular shape on the protection layer 28. The pixel electrode 30, herein may function as an anode, provides positively-charged holes to the light emitting layer 50. The pixel electrode 30 is made of a transparent substance such as ITO (indium tin oxide), IZO (indium zinc oxide), etc.

The wall 40 is formed around the circumference of the pixel electrode 30 between neighboring pixel electrodes 30 and is at least partly spaced apart from the nearest pixel electrode 30. The wall 40 prevents the pixel electrodes 30 from short-circuiting with each other and defines the pixel area A. The pixel electrode 30 disposed on the contact hole 27, electrically connecting the pixel electrode 30 to the TFT 20. As shown in FIG. 1, the portion of the pixel electrode 30 is covered with the wall 40 (marked with shading in FIG. 1).

The wall 40 may be a multi-layer structure, and is formed as a double-layer structure in the embodiment. A lower layer 41 of the wall 40 is made of an inorganic layer, (e.g., SiO2), and an upper layer 42 of the wall 40 is made of an organic substance. The wall 40 is generally hydrophobic because the organic substance in the upper layer 42 makes up most of the wall 40. When a light-emitting substance, which is usually hydrophilic, is dropped around the wall 40, it tends to migrate toward the pixel electrode 30 due to the hydrophobicity of the wall 40. For this reason, it is difficult to deposit the light-emitting substance near the edge of the wall 40. Thus, the hydrophobicity of the wall 40 can lead to formation of a defective pixel that contains a non-uniform light emitting layer.

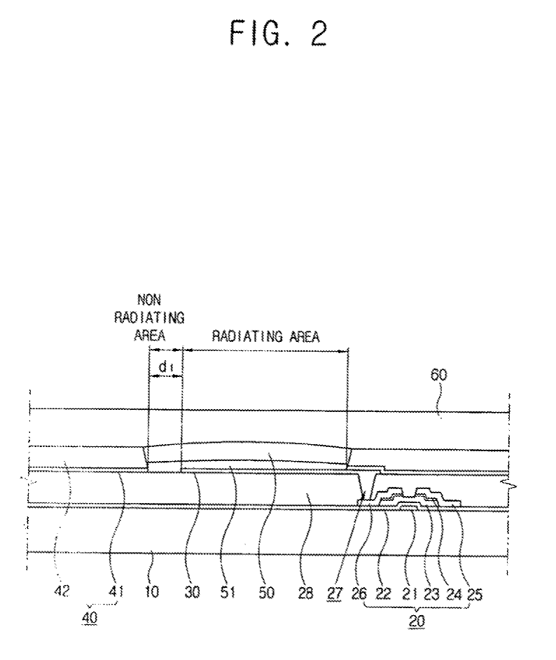

Accordingly, in the display device 1 of the embodiment as shownin FIG. 1, the wall 40 is spaced apart from the pixel electrode 30 by a predetermined distance. The pixel area A is an exposed area surrounded by the wall 40 at one point in the manufacturing process. The pixel area A is formed in a rectangular shape around the pixel electrode 30, as shown in FIG. 1. A portion of the pixel area A does not overlap the pixel electrode 30. In this area of pixel area A that does not have the pixel electrode 30, the protection layer 28 is exposed. The light emitting layer 30 is formed on the pixel area A between the walls 40. As shown in FIG. 2, the upper sides of the TFT 20 and the contact hole 27 are covered with the wall 40, but the pixel electrode 30 is spaced apart from the wall 40. Since the pixel electrode 30 is spaced apart from the wall 40, the protection layer under the pixel electrode 30 is exposed. A hole injection layer 51 and the light emitting layer 50 are formed on the exposed portion of the protection layer 28. Light is generated in a portion of the pixel electrode 30 where the wall 40 is not formed (shown as the “radiating area” in FIG. 2). The gap between the pixel electrode 30 and the wall 40 where the protection layer 28 is exposed is shown as the “non-radiating area.”

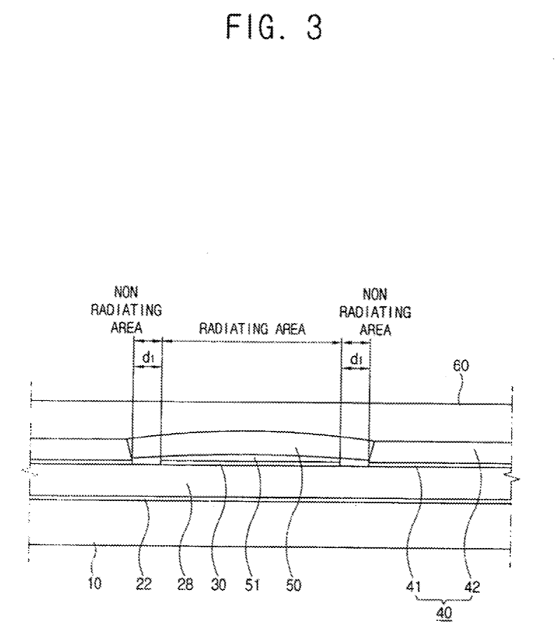

As shown in FIG. 3, both ends of the pixel electrode 30 are spaced apart from the wall 40. Light is generated only in the light emitting layer 50 formed on the pixel electrode 30. Although the light emitting layer 50 is formed between the walls 40, light is not generated from the light emitting layer 50 that does not overlap the pixel electrode 30 because there is no source providing the holes.

A distance d1 of the non-radiating area indicates the distance by which the pixel electrode 30 is spaced from the wall 40. Typically, the distance d1 is in the range of 0.5 μm-30 μm. The distance d1 may vary depending on the processing margin or aperture ratio. Furthermore, the distance d1 may be different if it is adjacent to the short side of the rectangular pixel electrode 30 than if it is adjacent to the long side, due to the different wire connections in those portions of the pixel electrode 30.

Typically, the wall 40 overlaps the pixel electrode 30 and the light-emitting substance is not properly formed on the edge of the wall 40 where the wall 40 and the pixel electrode 30 overlap. However, in the invention, the pixel electrode 30 is not formed on the edge of the wall 40. Thus, the problem of defective pixel being generated from non-uniform ink deposition on the edge of the wall 40 is solved. In the invention, even if the edge of the wall 40 is not filled with light-emitting substance and the light emitting layer 50 is not formed uniformly, there is no concern for short-circuiting the common electrode 60 because there is no pixel electrode 30 near the edge of the wall 40.

The hole injection layer 51 and the light emitting layer 50 are formed between the walls 40. The hole injection layer 51 is made of hole injecting substance such as PEDOT (poly 3,4-ethylenedioxythiopene) and PSS (polystyrenesulphonic acid) and is prepared by mixing the hole injecting substance and water. The mixture may be deposited by ink-jet method in an aqueous suspension state.

The light emitting layer 50 is formed on the hole injection layer 51. Excitons are generated when holes transmitted from the pixel electrode 30 combine with electrons transmitted from the common electrode 60 in the light emitting layer. Light is generated when the excitons give off energy during the inactivating process.

The light emitting layer 50 is made of a polymer and contains a substance capable of emitting blue light, red light and yellow light.

The common electrode 60 is disposed on the light emitting layer 50. The common electrode 60 provides electrons to the light emitting layer 50. The common electrode 60 may be made of an opaque substance like aluminum. In this case, light from the light emitting layer 50 exits through the insulating substrate 10, making the display device 1 a bottom-emission type device.

Although not shown in drawings, the display device 1 may also include a hole transfer layer between the hole injection layer 51 and the light emitting layer 50 and an electron transfer layer and an electron injection layer between the light emitting layer 50 and the common electrode 60. Use of a hole transfer layer and an electron transfer layer in an OLED is well-known. Also, it may further have an outer protective layer to protect the common electrode 60 and prevent moisture and air from infiltrating into the light emitting layer 50.

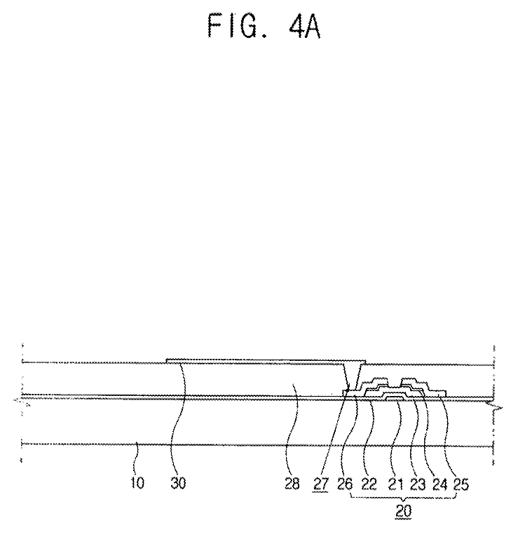

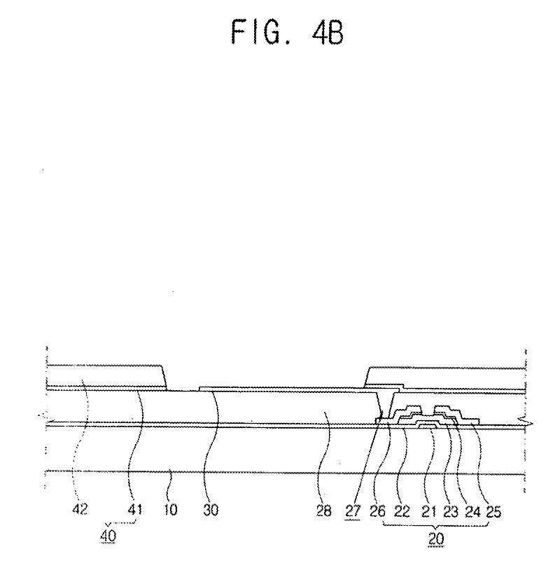

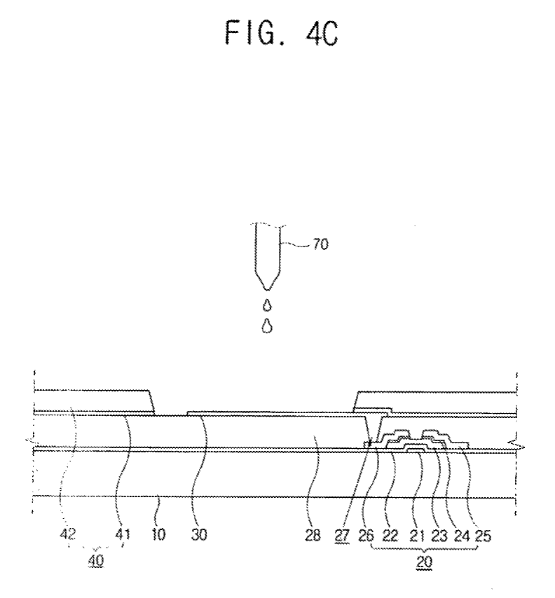

FIGS. 4a through 4c describes a manufacturing method of the display device 1 according to-the first embodiment of the present invention.

First, the TFT 20 is formed on the insulating substrate 10 in FIG. 4A. The channel of the TFT 20 is made of amorphous silicon and is formed by any of the suitable well-known methods. Thereafter, the protection layer 28 is deposited on the TFT 20. If the protection layer 28 is made of silicon nitride, CVD (chemical vaporization deposition) may be used. Then, the protection layer 28 is patterned by photolithography, thereby forming the contact hole 27 through which the drain electrode 26 is exposed. Next, the pixel electrode 30 is formed, connected to the drain electrode 26 through the contact hole 27. The pixel electrode 30 is deposited with ITO by the sputtering method and patterned. The pixel electrode 30 (the anode) provides holes to the light emitting layer 50.

Then, the wall 40 is formed between the adjacent pixel electrodes 30 as shown in FIG. 4B. The wall 40 is formed as a double-layered structure having the lower layer 41 that is made of an inorganic layer (e.g., SiO₂) and the upper layer 42 that is made of an organic substance. The wall 40 is formed in multiple layers by depositing and patterning the substance forming the layers. Further, the wall 40 has a taper structure, which decreases in a cross-sectional area to the higher part. The wall 40 is disposed on the TFT 20 and the contact hole 27.

Thereafter, the hole injection layer 51 and the light emitting layer 50 are formed on the portion of the pixel electrode 30 that is not covered with the wall 40, as shown in FIG. 4C. The hole injection layer 51 and the light emitting layer 50 are also formed on the portion of the protection layer 28 that is not covered by the pixel electrode 30. The hole injection layer 51 and the light emitting layer 50 are formed by an ink-jet method which entails dropping a fluid using a nozzle 70. The nozzle 70 filled with the hole injection substance and the light-emitting ink, respectively. The nozzle 70 moves over the insulating substrate 10 and drops the hole injection substance and the light-emitting ink on a predetermined area. Although not shown in the drawings, the display device includes a controller controlling to position of the nozzle 70 and the release of the fluid.

The hole injecting layer 51 and the light emitting layer 50 may be formed by dissolving the ink in a solvent and using nozzle coating or a spin coating.

Finally, the display device 1 shown in FIG. 2 is completed when the common electrode 60 is formed on the light emitting layer 50.

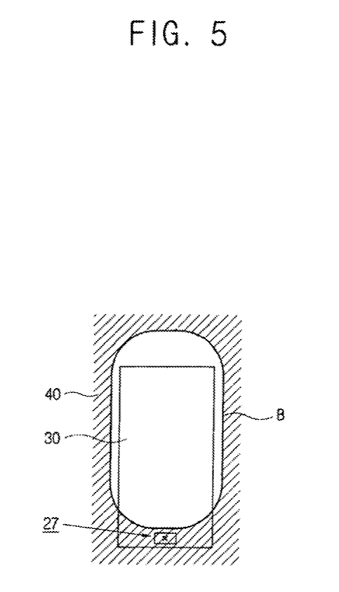

FIG. 5 shows a pixel area B of a display device according to a second embodiment of the present invention. The pixel area B surrounded by a wall 40 is formed in a rectangular shape having round corners. The degree of the roundedness of the corners and the shape of the rounded rectangle may be variable.

Since the wall 40 is mostly formed in a rectangular shape, a conventional pixel area usually has straight edges with right-angled or acute-angled corners. The light emitting layer 50 is not properly formed near the edges of the pixel area due to the surface tension of fluid trying to maintain a round shape such as a circle shape or an oval shape. In the invention, this problem is eliminated by rounding or curving the edges of the wall 40, thereby allowing the pixel area B to be properly filled with the light emitting layer 50.

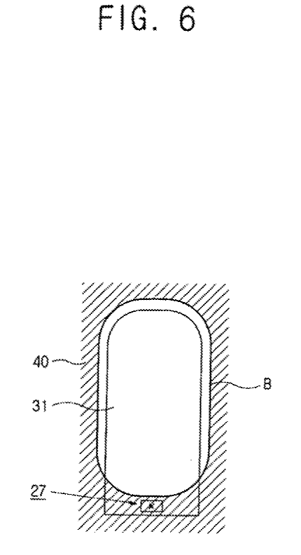

FIG. 6 shows a pixel area of a display device according to a third embodiment of the present invention. A pixel electrode 31 is formed in an oval shape, not in the conventional rectangular shape. The pixel area B formed by the wall 40 is the same as in FIG. 5 but the shape of the pixel electrode 31 is different from the embodiment of FIG. 5. When the pixel electrode 31 is rounded similarly to the pixel area B, aperture ratio is improved and it becomes easy to form the wall 40 along the edges of the pixel electrode 31.

The shape of pixel area A, B exposed by the pixel electrode 30, 31 and the wall 40 are not limited to the above-mention embodiments.

Although a few embodiments of the present invention have been shown and described, it will be appreciated by those skilled in the art that changes may be made in these embodiments without departing from the principles and spirit of the invention, the scope of which is defined in the appended claims and their equivalents.

1.-2. (canceled)

3. A display device comprising:
a plurality of thin film transistors (TFTs);
a protection layer formed on the TFTs;
a plurality of pixel electrodes formed on the protection layer and electrically connected to the TFTs;
a wall formed around the pixel electrode and spaced apart from at least a portion of the pixel electrode; and
a light emitting layer formed between the wall and another wall;
wherein the wall is formed around a pixel area and the shape of the pixel area has at least one curved edge.

4. (canceled)

5. A display device comprising:
a plurality of thin film transistors (TFTs);
a protection layer formed on the TFTs;
a plurality of pixel electrodes formed on the protection layer and electrically connected to the TFTs;
a wall formed around the pixel electrode and spaced apart from at least a portion of the pixel electrode; and
a light emitting layer formed between the wall and another wall;
wherein the shape of the pixel electrode has at least one curved portion.

6.-13. (canceled)

14. A display device comprising:
a plurality of thin film transistors (TFTs);
a protection layer formed on the TFTs;
a plurality of pixel electrodes formed on the protection layer and electrically connected to the TFTs;
a wall at least partly exposing the protection layer and formed around at least a portion of the pixel electrode; and
a light emitting layer formed between the wall and a neighboring wall;
wherein the wall forms around a pixel area, wherein the shape of pixel area has at least one curved portion.

15.-16. (canceled)

17. A method of manufacturing a display device comprising:
forming a plurality of thin film transistors (TFTs) on an insulating substrate;
depositing a protection layer on the TFTs and the insulating substrate;
forming a plurality of pixel electrodes on the protection layer, wherein the pixel electrodes are electrically connected to the TFTs;
forming a wall around the pixel electrode, wherein at least portion of the wall is spaced apart from the pixel electrode; and
forming a light emitting layer between the wall and a neighboring wall.

18. The method according to claim 17, wherein the light emitting layer is formed by an ink-jet method.

19. The method of claim 17, further comprising forming a common electrode on the light emitting layer.
